(19) United States
(12) Patent Application Publication
(10) Pub. No.: US 2025/0038712 A1
(43) Pub. Date: Jan. 30, 2025

(54) LOAD DRIVE CIRCUIT CAPABLE OF STOPPING OPERATING UPON OCCURRENCE OF ABNORMALITY, AND METHOD OF CONTROLLING LOAD DRIVE CIRCUIT

(71) Applicant: Yutaka OGAWA, Tokyo (JP)

(72) Inventor: Yutaka OGAWA, Tokyo (JP)

(73) Assignee: MITSUMI ELECTRIC CO., LTD., Tokyo (JP)

(21) Appl. No.: 18/773,993

(22) Filed: Jul. 16, 2024

(30) Foreign Application Priority Data
Jul. 28, 2023 (JP) 2023-123067

(51) Int. Cl. H03F 1/52

(52) U.S. Cl. CPC H03F 1/52; H03F 2200/03; H03F 2200/447; H03F 2200/468; H03F 2200/471

(57) ABSTRACT

Load drive circuit includes: drive circuit configured to receive power source voltage from power source circuit, drive a load while receiving enable signal at enable level, and stop driving the load while receiving enable signal at disable level, the power source circuit being configured to reduce the power source voltage in response to a power source current exceeding a limit value; a voltage reduction detection circuit configured to output first detection signal at enable level when the power source voltage is lower than first voltage, and output first detection signal at disable level when the power source voltage is equal to or higher than first voltage; and an enable control circuit configured to output enable signal at disable level based on first detection signal being at enable level, and output enable signal at enable level based on first detection signal being at disable level.

### CROSS-REFERENCE TO RELATED APPLICATION

The present application claims priority under 35 U.S.C. § 119 to Japanese Patent Application No. 2023-123067, filed Jul. 28, 2023, the contents of which are incorporated herein by reference in their entirety.

### BACKGROUND OF THE INVENTION

### Field of the Invention

The present disclosure relates to a load drive circuit capable of stopping operating upon occurrence of an abnormality, and a method of controlling a load drive circuit.

### Description of the Related Art

A class D amplification circuit, a class B amplification circuit, and the like that are configured to drive a loudspeaker, which is a load, and to output a sound from the loudspeaker have been known (for example, see Japanese Patent Application Laid-Open Publication No. 2014-72613).

### SUMMARY OF THE INVENTION

For example, in a loudspeaker system in which an amplification circuit configured to drive a loudspeaker and the loudspeaker are mounted on a substrate, short-circuiting across a +terminal and a −terminal of the loudspeaker due to dust or the like attached to the substrate has a risk of causing an abnormal current to flow through the amplification circuit. It is possible to detect an abnormal current in the amplification circuit due to short-circuiting, by detecting a temperature rise in the amplification circuit using a thermal shutdown circuit or the like.

However, in a case where a regulator is used as a power source of the amplification circuit, there is a fear that the thermal shutdown circuit may fail to detect a temperature rise and it may be impossible to detect an abnormal current, because the regulator has a protection function for reducing the power source voltage in response to the power source current exceeding a limit current, and this may reduce the abnormal current.

Moreover, in a case where a plurality of functional circuits including an amplification circuit are integrated on one chip, the chip size and the package size become large, and this may increase the number of terminals of the package. When there are many terminals, the amount of heat dissipated from the package is large, resulting in a high allowable power dissipation. Thus, there is a fear that the thermal shutdown circuit may fail to detect a temperature rise accompanying an abnormal current and it may be impossible to detect the abnormal current.

An object of the technique of the present disclosure is to stop a drive circuit upon detecting an abnormal current in the drive circuit, which occurs along with an abnormality in a load driven by the drive circuit, even in a case where it is impossible to detect the abnormal current in the form of a temperature rise.

To achieve the above technical object, a load drive circuit according to an embodiment of the present disclosure includes:
a drive circuit configured to receive a power source voltage from a power source circuit, to drive a load while the drive circuit is receiving an enable signal at an enable level, and to stop driving the load while the drive circuit is receiving the enable signal at a disable level, the power source circuit being configured to reduce the power source voltage in response to a power source current exceeding a limit value;
a voltage reduction detection circuit configured to output a first detection signal at an enable level when the power source voltage is lower than a first voltage, and to output the first detection signal at a disable level when the power source voltage is equal to or higher than the first voltage; and
an enable control circuit configured to output the enable signal at the disable level based on the first detection signal being at the enable level, and to output the enable signal at the enable level based on the first detection signal being at the disable level.

It is possible to stop a drive circuit upon detecting an abnormal current in the drive circuit, which occurs along with an abnormality in a load driven by the drive circuit, even in a case where it is impossible to detect the abnormal current in the form of a temperature rise.

### BRIEF DESCRIPTION OF THE DRAWINGS

FIG. 1 is a block diagram illustrating an example of a system including a load drive circuit according to a first embodiment;

FIG. 2 is a graph illustrating an example of an output voltage vs. output current characteristic of a regulator of FIG. 1;

FIG. 3 is a timing chart illustrating an example of an operation of the load drive circuit of FIG. 1;

FIG. 4 is a block diagram illustrating an example of a system including a load drive circuit according to a second embodiment;

FIG. 5 is a block diagram illustrating an example of a system including a load drive circuit according to a third embodiment; and

FIG. 6 is a block diagram illustrating an example of a system including a load drive circuit according to a fourth embodiment.

### DETAILED DESCRIPTION OF THE DISCLOSURE

Embodiments will be described below with reference to the drawings. In the following description, a signal line, a terminal, and a node to which a signal is transmitted may be denoted by the same reference numeral as that that is used for the signal name, and a voltage line, a terminal, and a node to which a voltage is transmitted, and the voltage value may be denoted by the same reference numeral as that that is used for the voltage name. In the drawings, the same components may be denoted by the same reference numerals, and duplicate descriptions may be omitted.

### First Embodiment

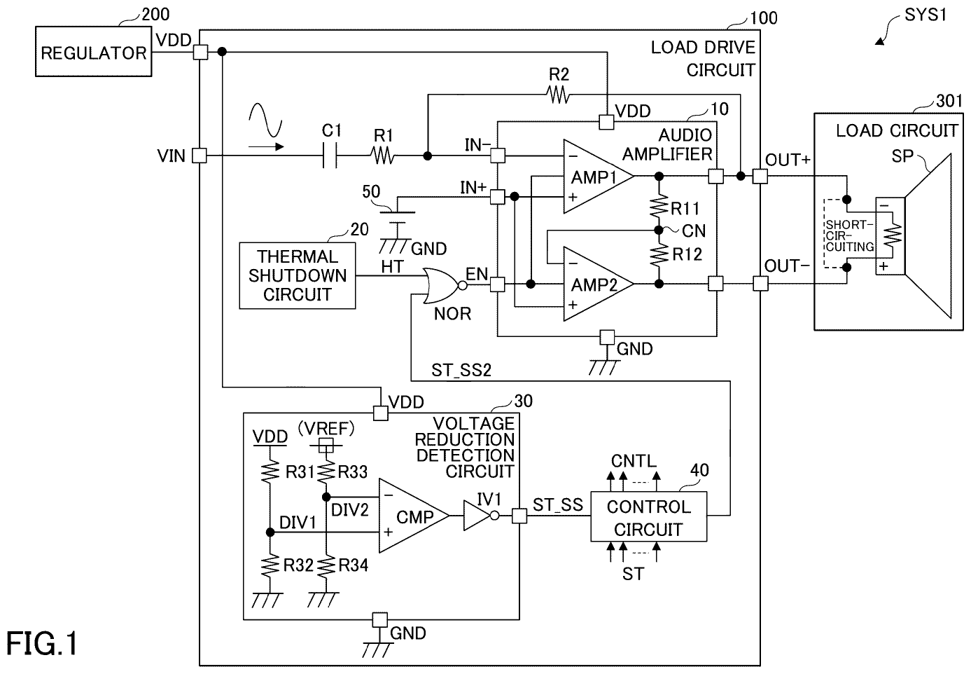

FIG. 1 is a block diagram illustrating an example of a system including a load drive circuit according to a first embodiment. For example, a system SYS1 illustrated in FIG. 1 includes a load drive circuit 100, a regulator 200, and a load circuit 301 such as a loudspeaker SP or the like, and functions as a sound output system. For example, the load drive circuit 100 has a form of a semiconductor chip, and is mounted on a substrate together with the regulator 200 and the load circuit 301 (loudspeaker SP). Thus, the system SYS1 may have a form of a substrate. The regulator 200 may be provided within the chip of the load drive circuit 100. The regulator 200 is an example of a power source circuit configured to reduce a power source voltage in response to a power source current exceeding a limit value.

An output of the regulator 200 is connected to a power source terminal VDD of the load drive circuit 100. Each circuit in the load drive circuit 100 is configured to operate by receiving a power source voltage VDD generated by the regulator 200. Output terminals OUT+ and OUT− of the load drive circuit 100 are connected to a −terminal and a +terminal of the loudspeaker SP, respectively.

The load drive circuit 100 includes an audio amplifier 10, a thermal shutdown circuit 20, a voltage reduction detection circuit 30, a control circuit 40, a standard voltage generator 50, a capacitor C1, resistors R1 and R2, and a 2-input NOR circuit. The audio amplifier 10 includes differential amplifiers AMP1 and AMP2, and resistors R11 and R12. The voltage reduction detection circuit 30 includes a comparator CMP, an inverter IV1, and resistors R31, R32, R33, and R34. The audio amplifier 10 is an example of a drive circuit configured to drive the loudspeaker SP, which is the load.

The capacitor C1 and the resistor R1 are connected in series between an input terminal VIN of the load drive circuit 100 and an input terminal IN− of the audio amplifier 10, and function as a filter. The resistor R2 is positioned between an output and a −input of the amplifier AMP1, and functions as a feedback resistor. An output terminal ST_SS of the voltage reduction detection circuit 30 is connected to an input of the control circuit 40. The two inputs of the NOR circuit are connected to a high temperature detection terminal HT of the thermal shutdown circuit 20 and an output terminal ST_SS2 of the control circuit 40, respectively. An output of the NOR circuit is connected to an enable terminal EN of the audio amplifier 10. The control circuit 40 and the NOR circuit are an example of an enable control circuit. The standard voltage generator 50 outputs a standard voltage to an input terminal IN+ of the audio amplifier 10.

The audio amplifier 10 operates while it is receiving an enable signal EN at a high level at the enable terminal EN, and stops operating while it is receiving the enable signal EN at a low level at the enable terminal EN. The resistors R11 and R12 are connected in series between the output of the amplifier AMP1 and an output of the amplifier AMP2, and a connection node CN at which the resistors R11 and R12 are connected is connected to a −input of the amplifier AMP2.

The amplifier AMP1 receives an alternating-current input signal VIN supplied via the capacitor C1 and the resistor R1 at its −input via the input terminal IN−, and receives the standard voltage at its +input via the input terminal IN+. The amplifier AMP1 inversely amplifies the input signal VIN received at its −input in accordance with the resistance ratio between the resistors R1 and R2, and outputs it as an output signal OUT+ to the output terminal OUT+. The −input and the +input of the amplifier AMP1 are an example of a pair of first input terminals. The output terminal OUT+ is an example of a first output terminal, and the output signal OUT+ is an example of a first output signal. The amplifier AMP2 receives the output signal OUT+ of the amplifier AMP1 at its −input via the resistor R11 and the connection node CN, and receives the standard voltage at its +input. The amplifier AMP2 inversely amplifies the signal received at its −input, and outputs it as an output signal OUT− to the output terminal OUT−. The −input and the +input of the amplifier AMP2 are an example of a pair of second input terminals. The output terminal OUT− is an example of a second output terminal, and the output signal OUT− is an example of a second output signal.

Through the above, the audio amplifier 10 inversely amplifies the input signal VIN and outputs it as the differential output signals OUT+ and OUT− to the −terminal and the +terminal of the loudspeaker SP. Then, a sound such as a voice or the like corresponding to the input signal VIN is output from the loudspeaker SP.

The thermal shutdown circuit 20 includes a transistor, and detects a temperature by utilizing the temperature dependency of a base-emitter voltage VBE of the transistor. The thermal shutdown circuit 20 outputs a high temperature detection signal HT at a high level to the NOR circuit when a detected temperature is equal to or higher than a predetermined temperature, and outputs the high temperature detection signal HT at a low level to the NOR circuit when a detected temperature is lower than the predetermined temperature.

The thermal shutdown circuit 20 is an example of a temperature detection circuit. The predetermined temperature is the maximum temperature at which the power consumed by the load drive circuit 100 does not exceed the allowable power dissipation, and is an example of a first temperature. The high temperature detection signal HT is an example of a second detection signal. The high level of the high temperature detection signal HT is an example of an enable level, and the low level of the high temperature detection signal HT is an example of a disable level.

In the voltage reduction detection circuit 30, the resistors R31 and R32 are connected in series between a power source line VDD and a ground line GND, and a voltage DIV1, which results from the power source voltage VDD being divided in accordance with the resistance ratio, is supplied to an input terminal + of the comparator CMP. The resistors R33 and R34 are connected in series between a reference voltage line VREF and the ground line GND, and a voltage DIV2, which results from the reference voltage VREF being divided in accordance with the resistance ratio, is supplied to an input terminal − of the comparator CMP. The reference voltage VREF is an example of a first voltage.

The comparator CMP detects that the power source voltage VDD is equal to or higher than the reference voltage VREF when the voltage DIV1 is equal to or higher than the voltage DIV2, and outputs a high level to the inverter IV1. The inverter IV1 receiving the high level outputs a voltage reduction detection signal ST_SS at a low level indicating that the power source voltage VDD is the normal value to the control circuit 40.

The comparator CMP detects that the power source voltage VDD is lower than the reference voltage VREF when the voltage DIV1 is lower than the voltage DIV2, and outputs a low level to the inverter IV1. The inverter IV1 receiving the low level outputs the voltage reduction detection signal ST_SS at a high level indicating that the power source voltage VDD is lower than the normal value to the control circuit 40.

The control circuit 40 receives state signals ST indicating the states of the various circuits mounted within the load drive circuit 100, and outputs various control signals CNTL in accordance with the state signals ST. The control circuit 40 outputs a voltage reduction detection signal ST_SS2 at a high level to the NOR circuit when the voltage reduction detection signal ST_SS is at the high level, and outputs the voltage reduction detection signal ST_SS2 at a low level to the NOR circuit when the voltage reduction detection signal ST_SS is at the low level.

The voltage reduction detection signals ST_SS and ST_SS2 are examples of a first detection signal. The high level of the voltage reduction detection signals ST_SS and ST_SS2 is an example of an enable level, and the low level of the voltage reduction detection signals ST_SS and ST_SS2 is an example of a disable level.

The NOR circuit outputs the enable signal EN at the low level to the enable terminal EN of the audio amplifier 10 in a case of receiving either or both of the high temperature detection signal HT at the high level and the voltage reduction detection signal ST_SS2 at the high level. The NOR circuit outputs the enable signal EN at the high level to the enable terminal EN of the audio amplifier 10 in a case of receiving the high temperature detection signal HT at the low level and the voltage reduction detection signal ST_SS2 at the low level.

By the above mechanism, the audio amplifier 10 stops operating in response to the thermal shutdown circuit 20 detecting a high temperature or in response to the voltage reduction detection circuit 30 detecting that the power source voltage VDD is lower than the normal value. The audio amplifier 10 operates while the thermal shutdown circuit 20 is not detecting a high temperature and the voltage reduction detection circuit 30 is detecting that the power source voltage VDD is the normal value.

For example, also when the load drive circuit 100 gets heated due to an abnormality or the like in a circuit included in the load drive circuit 100 while the power source current from the regulator 200 is not exceeding the limit current, the thermal shutdown circuit 20 can stop the audio amplifier 10 from operating. As a result, for example, it is possible to forestall occurrence of an abnormal current in the audio amplifier 10.

On the other hand, when a current higher than the limit current of the regulator 200 is flowing through the audio amplifier 10, the regulator 200 limits supplying the power source current to the audio amplifier 10. If this reduces the heating amount of the audio amplifier 10, it becomes difficult for the thermal shutdown circuit 20 to detect an abnormal current.

However, in the present embodiment, the regulator 200 limiting supplying the power source current is accompanied by a reduction in the power source voltage VDD that is output from the regulator 200. In a case of detecting a reduction in the power source voltage VDD, the voltage reduction detection circuit 30 outputs the voltage reduction detection signal ST_SS at the high level, to stop the audio amplifier 10 from operating. Thus, also in a case of the regulator 200 limiting the power source current, the load drive circuit 100 can detect an abnormal current in the audio amplifier 10, which may occur along with short-circuiting in the loudspeaker SP.

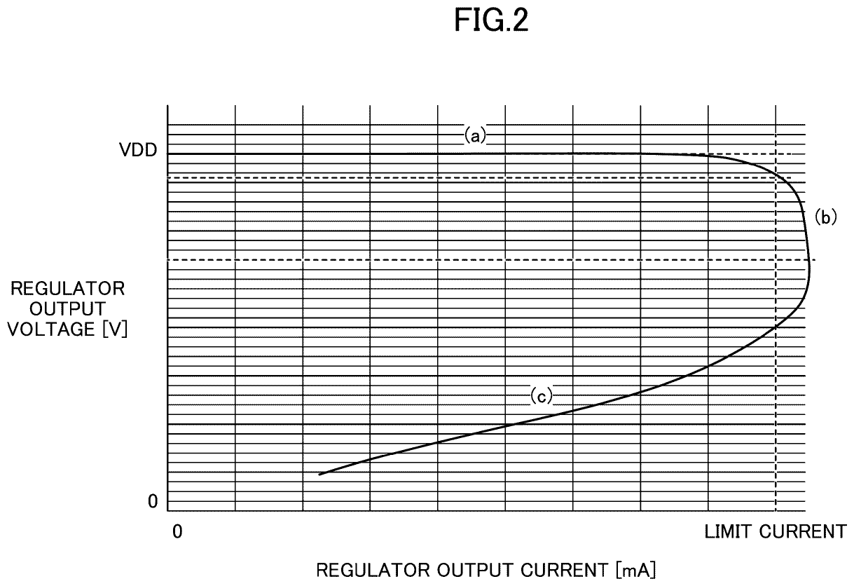

FIG. 2 is a graph illustrating an example of an output voltage vs. output current characteristic of the regulator 200 of FIG. 1. In a case where the load drive circuit 100 operates in accordance with the power source voltage VDD that is output from the regulator 200 and a predetermined power source current is consumed by the load drive circuit 100, the regulator 200 outputs a constant power source voltage VDD (FIG. 2, (a)).

On the other hand, in a case where the current consumed by the load drive circuit 100 increases due to short-circuiting in the loudspeaker SP or the like to exceed the limit current of the regulator 200, the regulator 200 activates the current limiting function to reduce the power source voltage VDD to output (FIG. 2, (b)). This reduces the power source current (regulator output current supplied to the load drive circuit 100 from the regulator 200 (FIG. 2, (c)), along with the reduction of the power source voltage VDD.

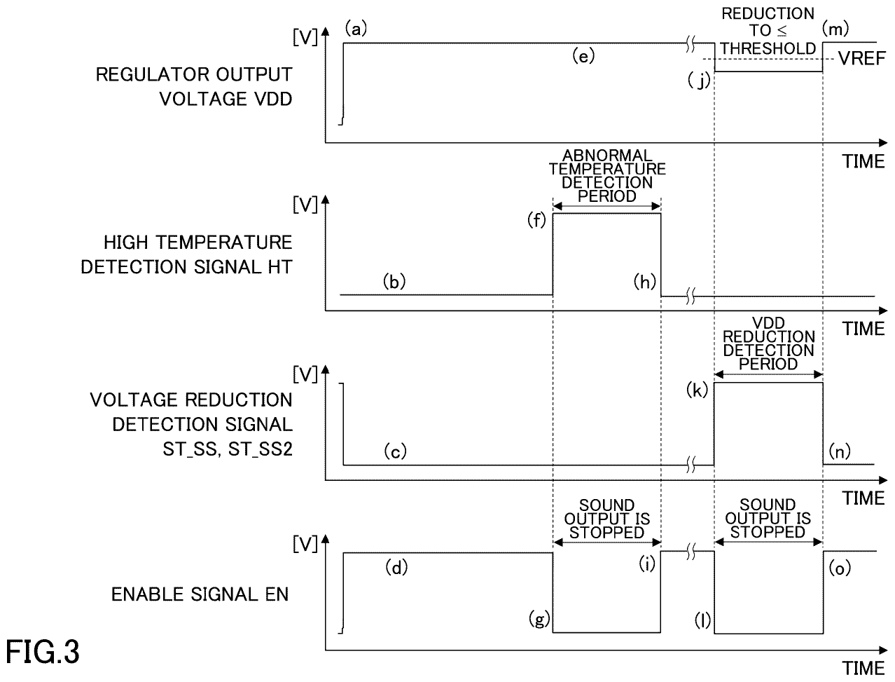

FIG. 3 is a timing chart illustrating an example of the operation of the load drive circuit 100 of FIG. 1. That is, FIG. 3 illustrates an example of a method of controlling the load drive circuit 100. First, in response to the power source of the system SYS1 being turned ON, the regulator 200 starts generating the power source voltage VDD, and the load drive circuit 100 starts operating (FIG. 3, (a)).

The thermal shutdown circuit 20 outputs the high temperature detection signal HT at the low level since it is not detecting a high temperature (FIG. 3, (b)). The voltage reduction detection circuit 30 outputs the voltage reduction detection signal ST_SS at the low level since the power source voltage VDD is the normal value, and the control circuit 40 outputs the voltage reduction detection signal ST_SS2 at the low level (FIG. 3, (c)).

The NOR circuit outputs the enable signal EN at the high level to the audio amplifier 10 based on the high temperature detection signal HT being at the low level and the voltage reduction detection signal ST_SS2 being at the low level (FIG. 3, (d)). Then, the audio amplifier 10 outputs the input signal VIN to the loudspeaker SP by differentially amplifying the voltage of the input signal VIN, to cause the loudspeaker SP to output a sound. Here, no short-circuiting occurs in the loudspeaker SP.

Subsequently, a certain part among the parts mounted on the system SYS1 including the load drive circuit 100 becomes a high temperature due to a certain cause, and the thermal shutdown circuit 20 detects a temperature abnormality. Here, since the power source current of the regulator 200 will not exceed the limit current by the high-temperature state of a part in the system SYS1 during an abnormal temperature detection period, the power source voltage VDD is maintained at the normal value (FIG. 3, (e)).

The thermal shutdown circuit 20 outputs the high temperature detection signal HT at the high level to the NOR circuit during the abnormal temperature detection period, and the NOR circuit outputs the enable signal EN at the low level to the audio amplifier 10 (FIG. 3, (f) and (g)). The audio amplifier 10 stops operating based on the enable signal EN being at the low level, and the loudspeaker SP stops outputting a sound.

Subsequently, the high-temperature state of the system SYS1 disappears, and the thermal shutdown circuit 20 changes the high temperature detection signal HT to the low level (FIG. 3, (h)). The NOR circuit outputs the enable signal EN at the high level to the audio amplifier 10 based on the high temperature detection signal HT being at the low level and the voltage reduction detection signal ST_SS2 being at the low level (FIG. 3, (i)). As a result, the loudspeaker SP resumes outputting a sound.

Subsequently, a temporary short-circuiting occurs across the −terminal and the +terminal of the loudspeaker SP. The temporary short-circuiting may occur due to absorption of moisture by dust or the like accumulated at the terminal portions of the loudspeaker SP. Due to the short-circuiting, a flow-through current flows between the output terminals OUT+ and OUT− of the load drive circuit 100. In a case where a power source current that is higher than the limit current is output from the regulator 200, the regulator 200 limits supplying the power source current, to reduce the power source voltage VDD (FIG. 3, (j)).

The voltage reduction detection circuit 30 outputs the voltage reduction detection signal ST_SS at the high level when the power source voltage VDD becomes lower than the reference voltage VREF, and the control circuit 40 outputs the voltage reduction detection signal ST_SS2 at the high level (FIG. 3, (k)). The NOR circuit outputs the enable signal EN at the low level to the audio amplifier 10 based on the voltage reduction detection signal ST_SS2 being at the high level (FIG. 3, (1)). The audio amplifier 10 stops operating during a VDD reduction detection period based on the enable signal EN being at the low level, and the loudspeaker SP stops outputting a sound.

Subsequently, the temporary short-circuiting across the −terminal and the +terminal of the loudspeaker SP is resolved, and the normal power source voltage VDD that is equal to or higher than the reference voltage VREF is output from the regulator 200 (FIG. 3, (m)). Since the power source voltage VDD becomes equal to or higher than the reference voltage VREF, the voltage reduction detection circuit 30 changes the voltage reduction detection signal ST_SS to the low level, and the control circuit 40 outputs the voltage reduction detection signal ST_SS2 at the low level (FIG. 3, (n)). The NOR circuit outputs the enable signal EN at the high level to the audio amplifier 10 based on the voltage reduction detection signal ST_SS2 being at the low level and the high temperature detection signal HT being at the low level (FIG. 3, (o)). As a result, the loudspeaker SP resumes outputting a sound.

The load drive circuit 100 does not need to include the thermal shutdown circuit 20. In this case, one input of the NOR circuit is set to the low level. The operation of the load drive circuit 100 in a case of the thermal shutdown circuit 20 not being provided is the same as represented by the operation waveforms of FIG. 3 except the high temperature detection signal HT of FIG. 3, which is omitted, and except that the enable signal EN does not change based on a high temperature detection signal HT. Moreover, the load drive circuit 100 does not need to include the control circuit 40. In this case, the voltage reduction detection signal ST_SS may be directly connected to the input of the NOR circuit.

In the first embodiment, upon detecting a reduction of the power source voltage VDD, the voltage reduction detection circuit 30 outputs the voltage reduction detection signal ST_SS at the high level, to stop the audio amplifier 10 from operating. Thus, even when the regulator 200 is limiting the power source current, the load drive circuit 100 can detect an abnormal current in the audio amplifier 10, which may occur along with short-circuiting in the loudspeaker SP. As a result, it is possible to stop the audio amplifier 10 upon detecting an abnormal current in the audio amplifier 10, which occurs along with an abnormality in the load circuit 301 driven by the audio amplifier 10, even in a case where it is impossible to detect the abnormal current in the form of a temperature rise.

Moreover, also when the load drive circuit 100 gets heated due to an abnormality or the like in a circuit included in the load drive circuit 100 while the power source current from the regulator 200 is not exceeding the limit current, the thermal shutdown circuit 20 can stop the audio amplifier 10 from operating.

### Second Embodiment

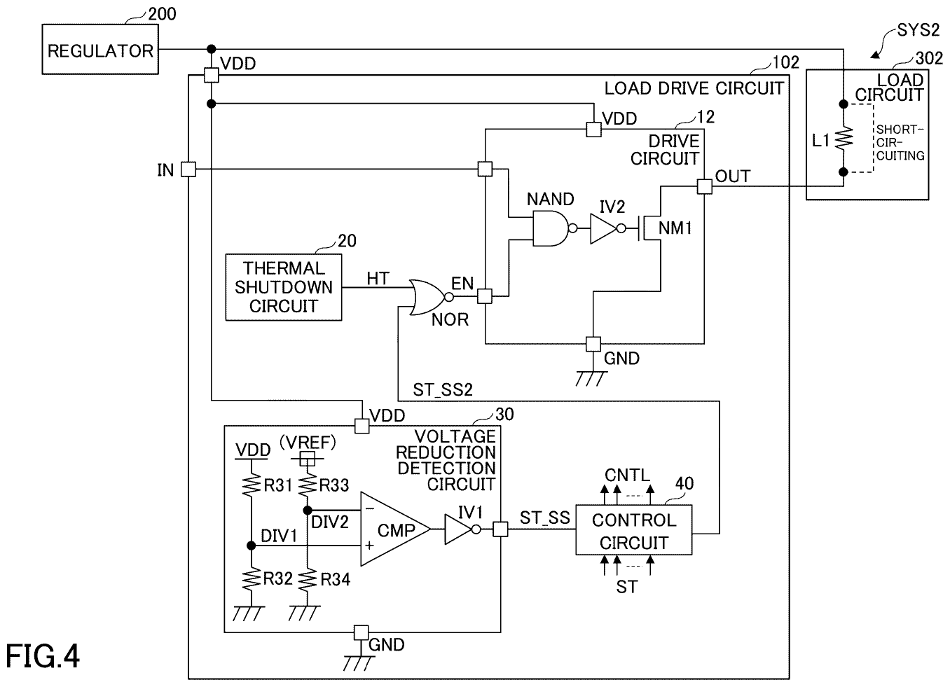

FIG. 4 is a block diagram illustrating an example of a system including a load drive circuit according to a second embodiment. The same components as in FIG. 1 will be denoted by the same reference numerals, and detailed description of such components will be omitted. A system SYS2 illustrated in FIG. 4 includes a load drive circuit 102, a regulator 200, and a load circuit 302. The load drive circuit 102 has the same components and functions as those of the load drive circuit 100 of FIG. 1, except that it includes a drive circuit 12 instead of the audio amplifier 10 of FIG. 1.

The drive circuit 12 includes a 2-input NAND circuit, an inverter IV2, and an open drain n-channel Metal Oxide Semiconductor (MOS) transistor NM1. In the following description, the n-channel MOS transistor NM1 will also be referred to simply as the transistor NM1.

One input of the NAND circuit is connected to an input terminal IN of the load drive circuit 102, and the other input of the NAND circuit is connected to an enable terminal EN. An output of the NAND circuit is connected to an input of the inverter IV2, and an output of the inverter IV2 is connected to the gate of the transistor NM1. The drain of the transistor NM1 is connected to the load circuit 302 via an output terminal OUT, and the source of the transistor NM1 is connected to a ground line GND.

For example, the load circuit 302 includes a load L1, which is equivalently represented as a resistor that is connected between a power source line VDD and the output terminal OUT of the drive circuit 12. For example, the load circuit 302 may be a Light Emitting Diode (LED). The drive circuit 12 operates while it is receiving an enable signal EN at a high level, and turns ON the transistor NM1 in accordance with an input signal IN at a high level to operate the load circuit 302. In response to receiving the enable signal EN at a low level, the drive circuit 12 turns OFF the transistor NM1 to stop operating the load circuit 302.

The load drive circuit 102 operates in the same manner as in FIG. 3. However, “sound output is stopped” in the low level period of the enable signal EN illustrated in FIG. 3 is replaced by “driving of the load circuit 302 by the transistor NM1 is stopped”.

The same effect as in the first embodiment can also be obtained in the second embodiment. For example, it is possible to stop the drive circuit 12 upon detecting an abnormal current in the drive circuit 12, which occurs along with an abnormality in the load driven by the drive circuit 12, even in a case where it is impossible to detect the abnormal current in the form of a temperature rise.

### Third Embodiment

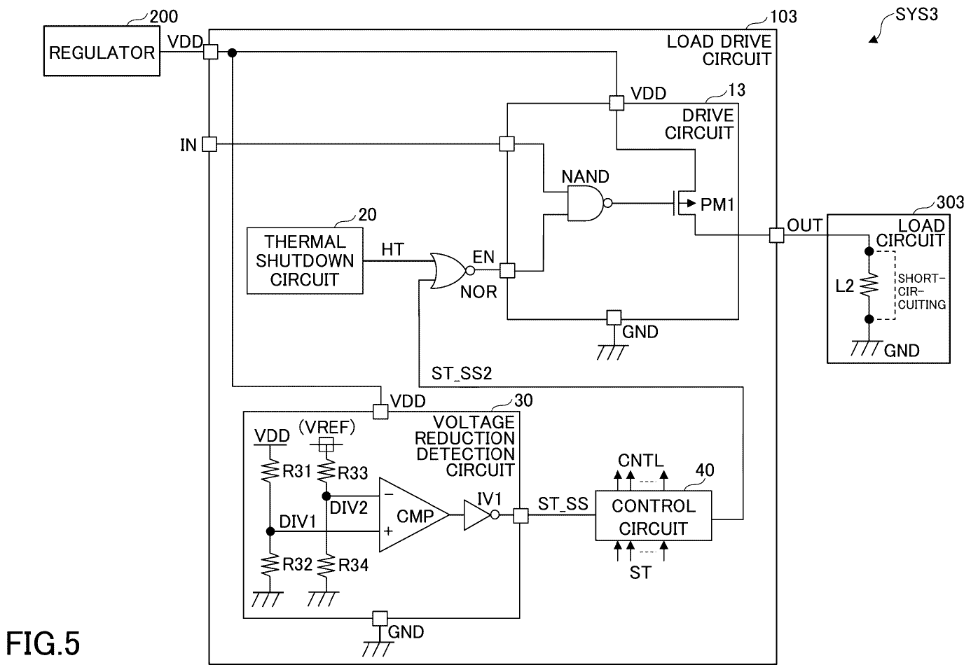

FIG. 5 is a block diagram illustrating an example of a system including a load drive circuit according to a third embodiment. The same components as in FIG. 1 and FIG. 4 will be denoted by the same reference numerals, and detailed description of such components will be omitted. A system SYS3 illustrated in FIG. 5 includes a load drive circuit 103, a regulator 200, and a load circuit 303. The load drive circuit 103 has the same components and functions as those of the load drive circuit 100 of FIG. 1, except that it includes a drive circuit 13 instead of the audio amplifier 10 of FIG. 1.

The drive circuit 13 includes a 2-input NAND circuit and an open drain p-channel MOS transistor PM1. In the following description, the p-channel MOS transistor PM1 will also be referred to simply as the transistor PM1.

One input of the NAND circuit is connected to an input terminal IN of the load drive circuit 103, and the other input of the NAND circuit is connected to an enable terminal EN. An output of the NAND circuit is connected to the gate of the transistor PM1. The drain of the transistor PM1 is connected to the load circuit 303 via an output terminal OUT, and the source of the transistor PM1 is connected to a power source line VDD.

For example, the load circuit 303 includes a load L2, which is equivalently represented as a resistor that is connected between the output terminal OUT of the drive circuit 13 and a ground line GND. The drive circuit 13 operates while it is receiving an enable signal EN at a high level, and turns ON the transistor PM1 in accordance with an input signal IN at a high level to operate the load circuit 303. In response to receiving the enable signal EN at a low level, the drive circuit 13 turns OFF the transistor PM1 to stop operating the load circuit 303.

The load drive circuit 103 operates in the same manner as in FIG. 3. However, “sound output is stopped” in the low level period of the enable signal EN illustrated in FIG. 3 is replaced by “driving of the load circuit 303 by the transistor PM1 is stopped”.

The same effect as in the first embodiment can also be obtained in the third embodiment. For example, it is possible to stop the drive circuit 13 upon detecting an abnormal current in the drive circuit 13, which occurs along with an abnormality in the load driven by the drive circuit 13, even in a case where it is impossible to detect the abnormal current in the form of a temperature rise.

### Fourth Embodiment

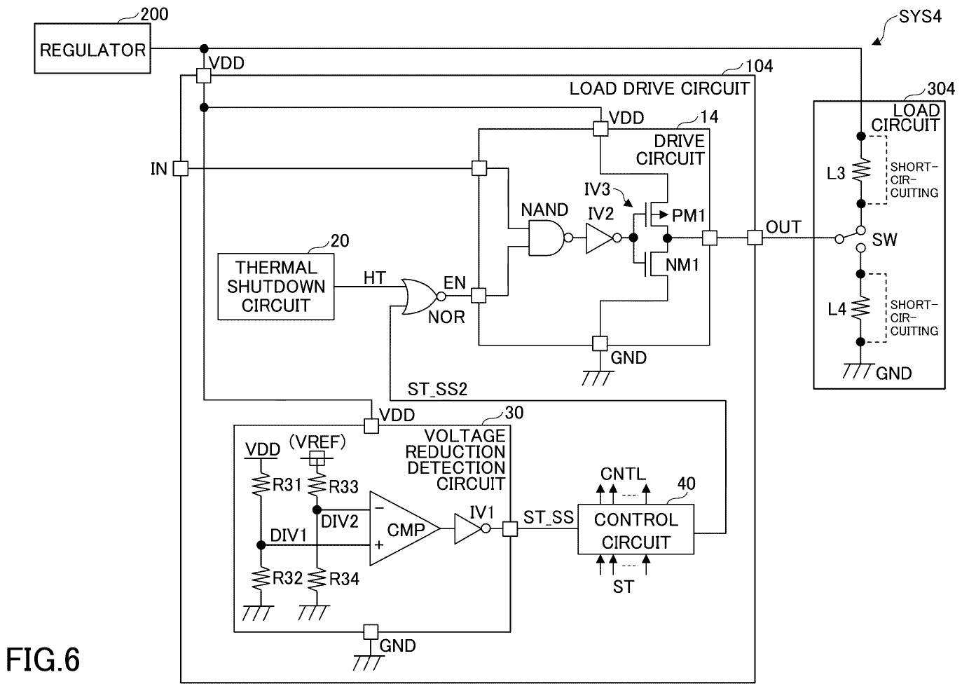

FIG. 6 is a block diagram illustrating an example of a system including a load drive circuit according to a fourth embodiment. The same components as in FIG. 1, FIG. 4, and FIG. 5 will be denoted by the same reference numerals, and detailed description of such components will be omitted. A system SYS4 illustrated in FIG. 6 includes a load drive circuit 104, a regulator 200, and a load circuit 304. The load drive circuit 104 has the same components and functions as those of the load drive circuit 100 of FIG. 1, except that it includes a drive circuit 14 instead of the audio amplifier 10 of FIG. 1.

The drive circuit 14 includes a 2-input NAND circuit, an inverter IV2, and a CMOS inverter IV3. The CMOS inverter IV3 includes transistors PM1 and NM1. The source of the transistor PM1 is connected to a power source line VDD, and the source of the transistor NM1 is connected to a ground line GND.

One input of the NAND circuit is connected to an input terminal IN of the load drive circuit 104, and the other input of the NAND circuit is connected to an enable terminal EN. An output of the NAND circuit is connected to an input of the CMOS inverter IV3 via the inverter IV2. An output of the CMOS inverter IV3 is connected to the load circuit 304 via an output terminal OUT.

For example, the load circuit 304 includes loads L3 and L4, and a switch SW. The load L3 is connected between the output terminal OUT of the drive circuit 14 and the power source line VDD. The load L4 is connected between the output terminal OUT of the drive circuit 14 and the ground line GND. The switch SW is configured to connect the output terminal OUT to either the load L1 or the load L2. The switching of the switch SW may be performed by the control circuit of the load drive circuit 104 or may be performed by another control circuit within the system SYS4.

The load drive circuit 104 operates in the same manner as the load drive circuit 102 of FIG. 4 in a first operation mode in which the switch SW connects the output terminal OUT to the load L3. The load drive circuit 104 operates in the same manner as the load drive circuit 103 of FIG. 5 in a second operation mode in which the switch SW connects the output terminal OUT to the load L4.

The same effect as in the first to third embodiments can also be obtained in the fourth embodiment. For example, it is possible to stop the drive circuit 14 upon detecting an abnormal current in the drive circuit 14, which occurs along with an abnormality in the load driven by the drive circuit 14, even in a case where it is impossible to detect the abnormal current in the form of a temperature rise.

The present disclosure has been described by way of the embodiments. However, the present disclosure is not limited to the requirements set forth in the embodiments described above. These particulars may be changed within the scope of the spirit of the present disclosure, and may be suitably defined in accordance with the mode of application.

What is claimed is:

1. A load drive circuit capable of stopping operating upon occurrence of an abnormality, the load drive circuit comprising:
a drive circuit configured to receive a power source voltage from a power source circuit, to drive a load while the drive circuit is receiving an enable signal at an enable level, and to stop driving the load while the drive circuit is receiving the enable signal at a disable level, the power source circuit being configured to reduce the power source voltage in response to a power source current exceeding a limit value;
a voltage reduction detection circuit configured to output a first detection signal at an enable level when the power source voltage is lower than a first voltage, and to output the first detection signal at a disable level when the power source voltage is equal to or higher than the first voltage; and
an enable control circuit configured to output the enable signal at the disable level based on the first detection signal being at the enable level, and to output the enable signal at the enable level based on the first detection signal being at the disable level.

2. The load drive circuit capable of stopping operating upon occurrence of an abnormality according to claim 1, the load drive circuit further comprising:
a temperature detection circuit configured to output a second detection signal at an enable level when a temperature is equal to or higher than a first temperature, and to output the second detection signal at a disable level when the temperature is lower than the first temperature,
wherein the enable control circuit outputs the enable signal at the disable level based on the first detection signal being at the enable level or the second detection signal being at the enable level, and outputs the enable signal at the enable level based on the first detection signal being at the disable level and the second detection signal being at the disable level.

3. The load drive circuit capable of stopping operating upon occurrence of an abnormality according to claim 1,
wherein the drive circuit is an audio amplifier comprising:
a first amplifier configured to receive at a pair of first input terminals thereof, an input signal that is input via a filter, and a standard voltage, respectively, and to output a first output signal via a first output terminal; and
a second amplifier configured to receive at a pair of second input terminals thereof, the standard voltage and a third voltage, respectively, and to output a second output signal via a second output terminal,
the third voltage is a voltage that is output from between resistors that are connected in series between the first output terminal and the second output terminal, and
the load is a loudspeaker configured to receive the first output signal at a first input terminal thereof, and to receive the second output signal at a second input terminal thereof.

4. A method of controlling a load drive circuit configured to drive a load by receiving a power source voltage from a power source circuit configured to reduce the power source voltage in response to a power source current exceeding a limit value, the method comprising:
driving the load while an enable signal at an enable level is being received, and stopping driving the load while the enable signal at a disable level is being received;
outputting a first detection signal at an enable level when the power source voltage is lower than a first voltage, and outputting the first detection signal at a disable level when the power source voltage is equal to or higher than the first voltage; and
outputting the enable signal at the disable level based on the first detection signal being at the enable level, and outputting the enable signal at the enable level based on the first detection signal being at the disable level.

5. The load drive circuit capable of stopping operating upon occurrence of an abnormality according to claim 2,
wherein the drive circuit is an audio amplifier comprising:
a first amplifier configured to receive at a pair of first input terminals thereof, an input signal that is input via a filter, and a standard voltage, respectively, and to output a first output signal via a first output terminal; and
a second amplifier configured to receive at a pair of second input terminals thereof, the standard voltage and a third voltage, respectively, and to output a second output signal via a second output terminal,
the third voltage is a voltage that is output from between resistors that are connected in series between the first output terminal and the second output terminal, and
the load is a loudspeaker configured to receive the first output signal at a first input terminal thereof, and to receive the second output signal at a second input terminal thereof.
